(19) United States
(12) Patent Application Publication
(10) Pub. No.: US 2011/0094784 A1
(43) Pub. Date: Apr. 28, 2011

(54) FLEXIBLE PRINTED CIRCUIT BOARD AND ELECTRONIC APPARATUS

(75) Inventors: Kiyomi MURO, Hachioji-shi (JP); Yasuki TORIGOSHI, Tachikawa-shi (JP)

(73) Assignee: KABUSHIKI KAISHA TOSHIBA, Tokyo (JP)

(21) Appl. No.: 12/975,167

(22) Filed: Dec. 21, 2010

Related U.S. Application Data
(63) Continuation of application No. 12/345,307, filed on Dec. 29, 2008.

(30) Foreign Application Priority Data
Mar. 28, 2008 (JP) 2008-086936

(51) Int. Cl. H05K 1/00; H05K 1/16

(52) U.S. Cl. 174/260; 174/250

(57) ABSTRACT

According to one embodiment, a plurality of conductive-paste-filling openings are provided in the cover layer to align with the conductive pattern portion, and a plurality of conductive portions are formed by filling conductive paste in the plurality of conductive-paste-filling openings to conductively join the metal layer to the conductive pattern portion.

### CROSS-REFERENCE TO RELATED APPLICATIONS

This application is a continuation of U.S. patent application Ser. No. 12/345,307, filed Dec. 29, 2008, which is based upon and claims the benefit of priority from Japanese Patent Application No. 2008-086936, filed Mar. 28, 2008, each of which is incorporated by reference herein in its entirety.

### BACKGROUND

1. Field

One embodiment of the invention relates to a flexible printed circuit board configured to transmit high-frequency signals, and to an electronic apparatus.

2. Description of the Related Art

Flexible printed circuit boards are often used for information processing apparatuses; the flexible printed circuit board can be mounted in a housing of the information processing apparatus in a bent condition, and offers a high degree of configurability. With the increased processing speed of the information processing apparatus and the increased density of circuits in the apparatus, even for the flexible printed circuit board, mounted in the housing of the apparatus, there has been a demand for a transmission line forming technique using printed circuitry for high-frequency-band signals with a transmission loss taken into account, in view of a change from a microwave (UHF) band to a centimeter wave (SHF) band, and further from the centimeter wave band to a millimeter wave (EHF) band.

For circuits with lower signal transmission rates, single end transmission lines are often used. In order to transmit signals in a high-frequency band of at least several hundred MHz, transmission lines are often used through which signals are transmitted based on a combination of the reduced voltage of the signal and a differential transmission scheme.

A conventional flexible printed circuit board with a transmission line based on the differential transmission scheme comprises a ground (GND) layer coated with a conductive paste (for example, a silver paste) so as to form a differential-signal transmission path with a specified rated impedance. Signals transmitted on the signal transmission path based on the differential transmission scheme use increasingly higher frequency bands. There has thus been a demand for formation of signal transmission lines compatible with the millimeter wave band. If the transmission line through which such high-frequency-band signals (for example, signals of about several hundred Mbps) are transmitted is formed of the ground layer comprising the conductive paste described above and a printed circuit layer made of copper, the transmission loss increases.

The conductive paste used for the ground layer in a common flexible printed circuit board has a volume resistivity of about 100 to 50 μΩ· cm. The resistance of the conductive paste (the resistance on the ground side) may cause a signal transmission loss at a transmission end for high-frequency signals. However, at the current signal transmission rate based on the differential signal transmission, for example, for Serial ATA (SATA-1; 1.5 Gbps), a signal transmission path is formed which operates as a normal circuit. However, for Serial ATA-2 with a higher signal transmission rate (SATA-2; 3 Gbps) or further faster signal transmission, the signal transmission loss further increases consistently with frequency band. This prevents normal signal transmission from being ensured.

Thus, efforts have been made to construct the ground layer using a metal nanopaste (for example, a silver nanopaste) with a lower volume resistivity instead of the above-described conductive paste. However, a metal film is formed by volatilizing a solvent from the wet nanopaste. Thus, a large amount of paste needs to be applied (to a thickness of about 40 to 50 μm) in order to evenly fill a current cover lay opening (with, for example, an aperture of about 0.8 to 1 mm). A large amount of nanopaste applied may vary finished thickness. As a result, when the nanopaste is dried and shaped, cracks are likely to occur as the nanopaste is contracted (cracks are likely to occur when the finished thickness exceeds 10 micrometers).

As a flexible printed circuit technique for constructing high-frequency transmission lines as described above, a flexible printed circuit board structure is known which comprises shielding layers each comprising a conductive adhesive and a metal foil and provided on a corresponding one of opposite surfaces of a signal layer, each of the shielding layers being connected to a ground circuit with the conductive adhesive, as shown in, for example, Jpn. Pat. Appln. KOKAI Publication No. 8-125380. However, the flexible printed circuit board structure with the shielding layers on the opposite surfaces is thick and is thus unsuitable for specifications involving configuration in a restricted path.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary sectional side view showing a configuration of an essential part of a flexible printed circuit board according to a first embodiment of the invention;

FIG. 2 is an exemplary plan view showing a configuration of an essential part of the flexible printed circuit board according to the first embodiment of the invention;

FIG. 3 is an exemplary enlarged plan view showing a part of the flexible printed circuit board;

FIG. 4 is an exemplary sectional side view showing Step A of manufacturing the flexible printed circuit board according to the first embodiment of the invention;

FIG. 5 is an exemplary sectional side view showing Step B of manufacturing the flexible printed circuit board according to the first embodiment of the invention;

FIG. 6 is an exemplary sectional side view showing Step C of manufacturing the flexible printed circuit board according to the first embodiment of the invention;

FIG. 7 is an exemplary sectional side view showing Step D of manufacturing the flexible printed circuit board according to the first embodiment of the invention;

FIG. 8 is an exemplary perspective view showing an outer appearance of a portable computer according to a second embodiment of the invention;

FIG. 9 is an exemplary perspective view showing a main body of the potable computer according to the second embodiment of the invention with a keyboard removed from the main body;

FIG. 10 is an exemplary perspective view of a hard disk drive incorporated in the portable computer according to the second embodiment of the invention and the case holding the hard disk drive, as viewed obliquely from below;

FIG. 11 is an exemplary perspective view of the hard disk drive and the case supporting the hard disk drive, which are provided in the portable computer according to the second embodiment of the invention, as viewed obliquely from above;

FIG. 12 is an exemplary side view illustrating how the flexible printed circuit board is arranged in the portable computer according to the second embodiment of the invention; and

FIG. 13 is an exemplary perspective view showing a part of the main body of the portable computer according to the second embodiment of the invention, with the keyboard, hard disk drive and case removed from the main body.

### DETAILED DESCRIPTION

Various embodiments according to the invention will be described hereinafter with reference to the accompanying drawings. In general, according to one embodiment of the invention, there is provided a flexible printed circuit board, comprising: a base layer, a signal layer formed on the base layer, a cover layer covering the signal layer, a conductive pattern portion provided in the signal layer, a metal layer formed on the cover layer, a protective layer formed on the metal layer, a plurality of conductive-paste-filling openings provided in the cover layer to align with the conductive pattern portion, and a plurality of conductive portions formed by filling conductive paste in the plurality of conductive-paste-filling openings to conductively join the metal layer to the conductive pattern portion.

### First Embodiment

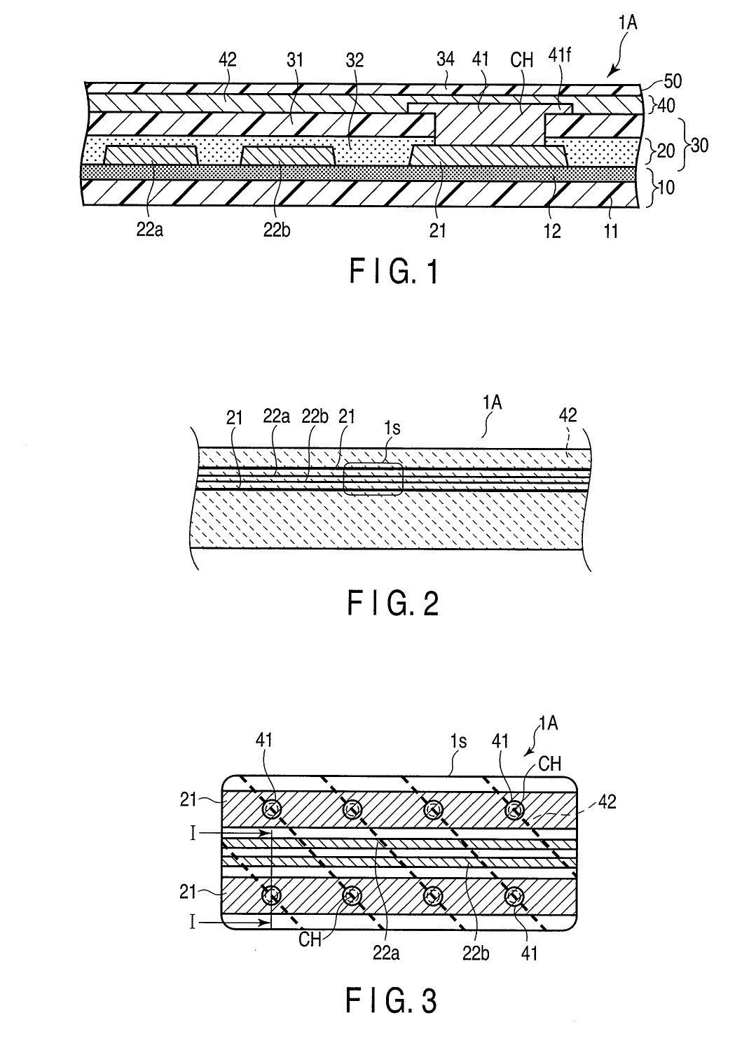

FIG. 1 is a sectional side view showing an essential part of a flexible printed circuit board according to a first embodiment of the invention. FIG. 2 is a plan view showing the configuration of the flexible printed circuit board. FIG. 3 is an enlarged plan view showing a part of the flexible printed circuit board shown in FIG. 2. The sectional side view of FIG. 1 is taken along line I-I shown in FIG. 3. FIG. 3 is an enlarged view of the part 1s of the configuration shown in FIG. 2.

As shown in FIG. 1, the flexible printed circuit board 1A according to the first embodiment comprises a base layer 10, a signal layer 20 formed on the base layer 10, a cover layer 30 covering the signal layer 20, a metal layer 40 formed on the cover layer 30, and a protective layer 50 formed on the metal layer 40, a conductive pattern portion 21 provided in the signal layer 20, a plurality of conductive-paste-filling openings CH each of which is shaped in form of a spot in a surface portion corresponding to the conductive pattern portion 21 in the cover layer 30 and which is made up of an opening, and a plurality of conductive portions 41 each comprising a conductive paste filled in the conductive-paste-filling opening CH to conductively join the metal layer 40 to the conductive pattern portion 21.

In the above-described configuration, the conductive pattern portion 21 makes up a ground line forming a current path for a DC power supply. Signal transmission lines 22a and 22b that connect transmission ends of information processing elements together are formed in the signal layer 20 in a pattern layout in which the ground line 21 extends along the signal transmission lines 22a and 22b. The metal layer 40 forms a ground layer for the signal transmission lines 22a and 22b.

In the configuration shown in FIG. 1, described above, the base layer 10 comprises a base-layer polyimide 11 and a base-layer adhesive 12. A surface of the base-layer adhesive 12 corresponds to a pattern forming surface of the signal layer 20 to form a trace layer with a copper pattern.

The signal layer 20 comprises the conductive pattern portion 21 and signal transmission lines 22a and 22b, formed on the base-layer adhesive 12 of the base layer 10, which servers as an insulating base. The conductive pattern portion 21 makes up the ground line forming the current path for the DC power supply. As shown in FIG. 2, the ground line 21 extends toward transmission ends together with the signal transmission lines 22a and 22b in a pattern layout in which the ground line 21 extends along the signal transmission lines 22a and 22b. In this embodiment, the signal transmission lines 22a and 22b are laid out as two parallel traces (copper patterns) on a surface of the base layer 10 (a surface of the base-layer adhesive 12), to form signal transmission paths based on a differential transmission scheme (i.e., differential-signal transmission paths). In a pattern layout shown in FIG. 3, the ground line 21 is provided on each of opposite sides of the differential-signal transmission lines 22a and 22b so as to extend along the differential-signal transmission lines 22a and 22b at a given distance from each of the differential-signal transmission lines 22a and 22b. The signal layer 20 has a pattern layout in which, besides the ground line 21 and the differential-signal transmission lines 22a and 22b, a plurality of transmission lines comprising those of a single end type extend almost parallel to one another.

As shown in FIG. 3, a plurality of conductive portions 41 are provided on the ground line 21 at predetermined intervals, in which each of the plurality of conductive portions 41 is formed by filling the conductive paste in the corresponding conductive-paste-filling opening CH, formed in the cover layer 30 as an opening. The conductive portions 41 conductively join the ground line 21 and the metal layer 40 together by means of solid columnar conductors. As shown in FIG. 1, the conductive portion 41 closes the conductive-paste-filling opening CH formed in the cover layer 30 to form a flat flange portion 41f on part of the cover-layer polyimide 31 in the cover layer 30. The metal layer 40 covers the cover layer 30 together with the flange portions 41f.

The cover layer 30 comprises cover-layer polyimide 31 and a cover-layer adhesive 32. The cover layer 30 is coated with the metal layer 40, which is coated with a protective layer 34.

The metal layer 40 forms a ground layer and an electromagnetic shielding layer for the differential-signal transmission lines 22a and 22b, formed in the signal layer 20. The metal layer 40 comprises a metal film 42 made of a silver nanopaste of a low volume resistivity (about several μΩ· cm). The metal film 42 is formed on a surface of the cover layer 30 so as to have a film thickness of at most 10 μm.

The flange portion 41f formed at a top portion of the conductive portion 41 is protrudingly provided on the surface of the cover layer 30 in form of a spot. The metal film 42 is a thin film, which has a film thickness of at most 10 μm and has a flat surface, is formed on the surface of the cover layer 30 so that a portion of the metal film 42 covered with the flange portion 41f forms a thinner film.

The protective layer 50 comprises an overcoat 34. The protective layer 50 covers the upper surface and sides of the metal layer 40 formed using a silver nanopaste.

As described above, conductive paste is filled in the conductive-paste-filling opening CH formed in the cover layer 30 to form the conductive portion 41, which conductively joins the ground line 21 and the metal layer 40 together. Consequently, the metal film 42 of film thickness of at most 10 μm can be easily formed in the metal layer 40, and the metal film 42 is formed using the silver nanopaste with the low volume resistivity and inflicts a reduced transmission loss on the differential-signal transmission lines 22a and 22b. The metal film 42, formed using the silver nanopaste, makes up a ground pattern offering a low resistance for the differential-signal transmission lines 22a and 22b over the entire length of the transmission lines 22a and 22b to form a ground layer causing a reduced transmission loss.

Thus, the flexible printed circuit board 1A of a single-sided shielding structure can be provided which is suitably applied to, for example, signal transmissions conforming to Serial ATA standards such as Serial ATA-2 (SATA2; 3 Gbps) and Serial ATA-3 (SATA-3; 6 Gbps) or other, equivalent or faster signal transmissions. Furthermore, the flexible printed circuit board 1A of a single-sided shielding structure can be provided which is suitably applied to a narrow space (a narrow gap portion corresponding to the entire space excluding component mounting areas).

Moreover, the amount of nanopaste applied to form the metal layer 40 can be minimized. Thus manufacturing yield can be improved, and the reduced film thickness serves to prevent the ground layer from being cracked, allowing flexibility to be improved. The nanopaste used for the metal film 42 is not limited to the silver nanopaste but may be any nanopaste of a low volume resistivity, for example, a nanopaste made of silver nanoparticles blended with gold nanoparticles.

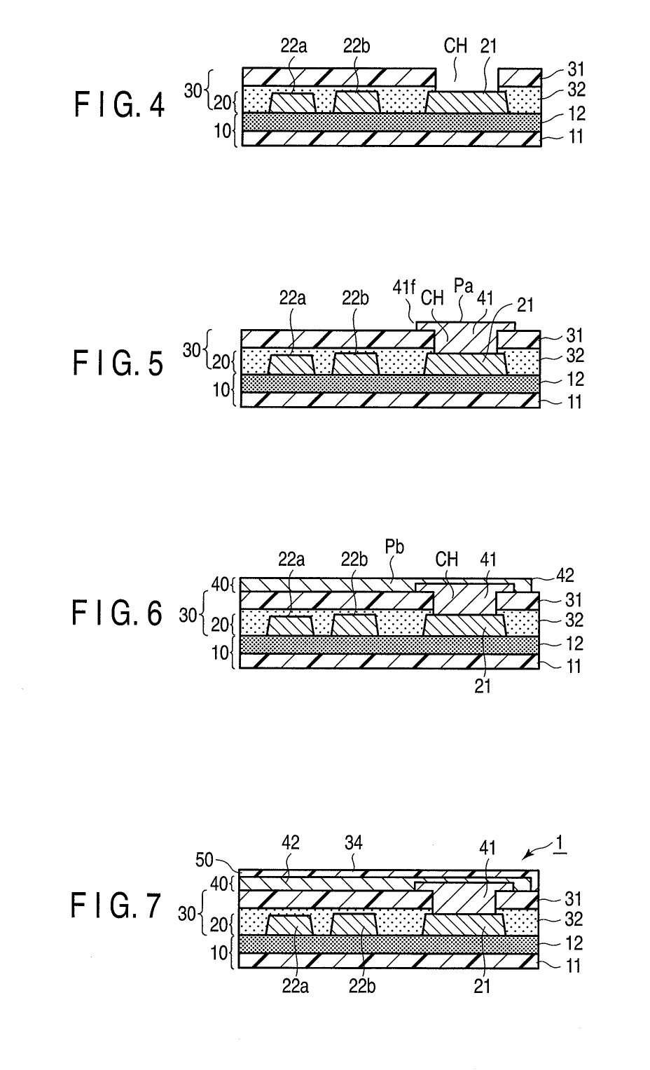

FIGS. 4 to 7 show a process of forming the conductive portion 41 in the flexible printed circuit board 1A. The process will be explained with reference to FIGS. 4 to 7 and also with reference to FIGS. 1 to 3.

As shown in FIGS. 1 to 3, according to a designed pattern layout, the patterns of the ground line 21 and the differential-signal transmission lines 22a and 22b are formed in the signal layer 20 which is provided on the base layer 10 comprising the base polyimide 11 and the base-layer adhesive 12. Based on the pattern layout, the plurality of conductive-paste-filling openings CH are provided in the cover layer 30 comprising the cover-layer polyimide 31 and the cover-layer adhesive 32, at the predetermined intervals to align with the ground line 21. The conductive-paste-filling opening CH are provided by cutting part of the cover layer 30 with laser beam, drilling, or the like.

In step A shown in FIG. 4, the cover layer 30 comprising the cover-layer polyimide 31 and the cover-layer adhesive 32 is formed on the base layer 10 comprising the base polyimide 11 and the base-layer adhesive 12. Specifically, the base-layer adhesive 12 of the base layer 10 is bonded to the cover-layer adhesive 32 of the cover layer 30, so that the signal layer 20 is interposed between the base layer 10 and the cover layer 30. In the cover layer 30 formed on the base layer 10, a pattern surface of the ground line 21 formed in the signal layer 20 is partly exposed from the conductive-paste-filling opening CH bored in the cover layer 30.

In step B shown in FIG. 5, a conductive paste Pa is filled into the conductive-paste-filling opening CH, from which the pattern surface of the ground line 21 is partly exposed, thereby forming the conductive portion 41 in the conductive-paste-filling opening CH. Specifically, a screen printing method is used to fill a determinate amount of conductive paste Pa into the conductive-paste-filling opening CH so that the conductive paste rises from the cover-layer polyimide 31, thereby forming the conductive portion 41 comprising the flat flange portion 41f on part of the cover-layer polyimide 31. Various conductive pastes are applicable as the applicable conductive paste Pa. The conductive paste Pa may be a silver paste, a gold and silver paste, a hybrid paste made of a blend of silver powder and silver nanoparticles, or the like.

In step C shown in FIG. 6, the metal layer 40 comprising the metal film 42 is formed on the conductive portion 41 and the cover layer 30. Specifically, a silver nanopaste Pb is coated on the cover-layer polyimide 31 of the cover layer 30 by the screen printing method or an ink jet method. The silver nanopaste Pb is then processed by being dried and hardened, to form the metal film 42 of thickness at most 10 μm on the cover-layer polyimide 31 of the cover layer 30.

The metal film 42 formed using the silver nanopaste Pb makes up the ground layer forming a ground pattern for the differential-signal transmission lines 22a and 22b provided in the signal layer 20.

In step D shown in FIG. 7, the surface and ends of the metal film 42 formed on the cover-layer polyimide 31 of the cover layer 30 is covered with the protective layer 50 comprising the overcoat 34.

Through the above-described steps, the conductive portions 41 like solid columns are formed, which conductively connect the ground line 21 and the metal layer 40 together at a plurality of positions in form of spots.

In the above-described steps, the thin metal film 42, which is conductively joined to the conductive portion 41, is formed by coating of the silver nanopaste. Instead, the metal film 42 may be formed by sputter coating or bonding of a metal foil with an adhesive, using, as a material (target), for example, metal such as copper (Cu), silver (Ag), gold (Au), aluminum (Al), or nickel (Ni), or an alloy of any of these metals.

### Second Embodiment

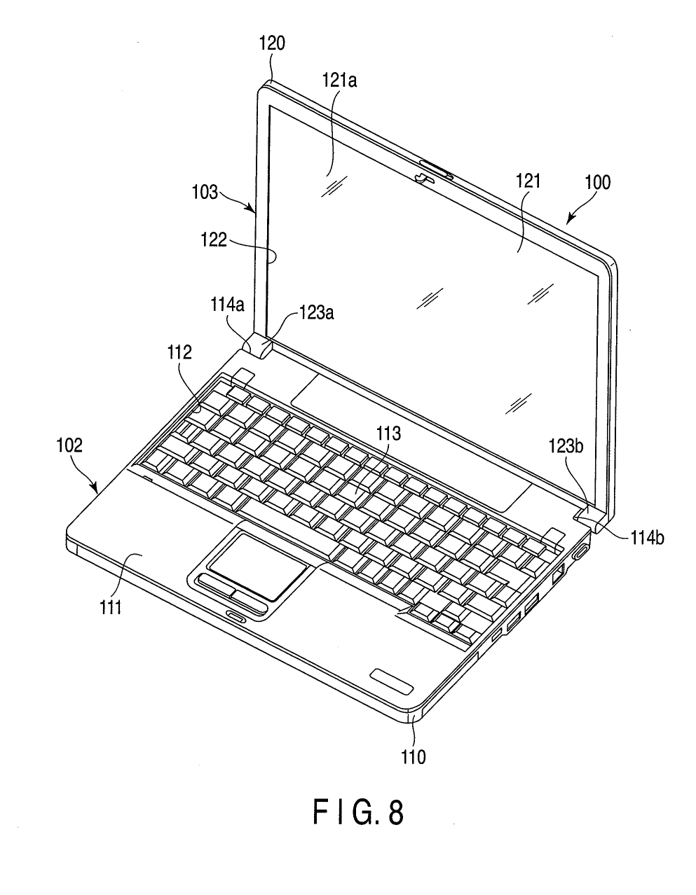

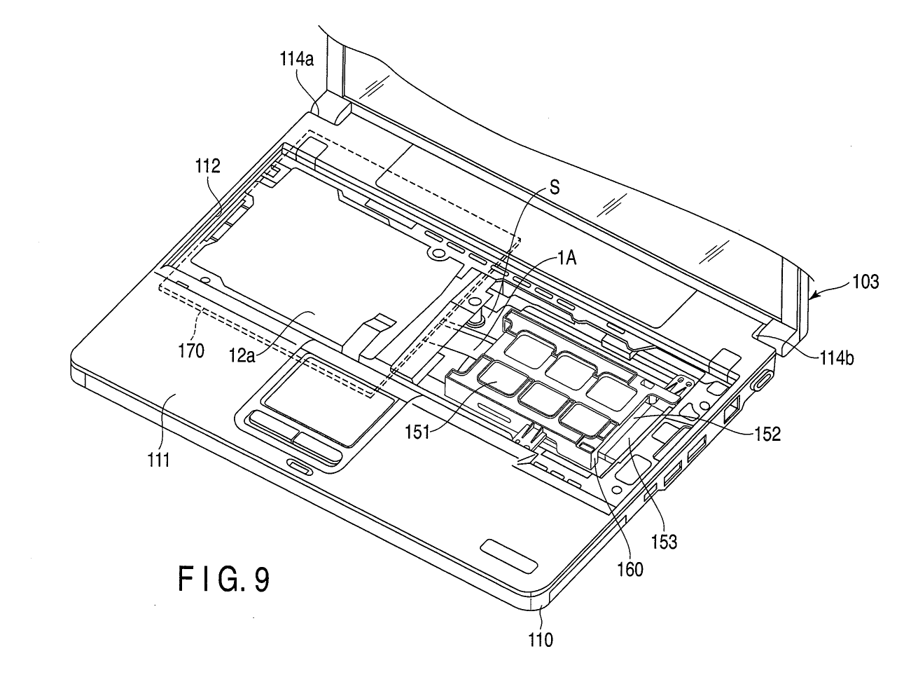

FIGS. 8 to 13 show a configuration of an electronic apparatus according to a second embodiment of the invention comprising, as a component, the flexible printed circuit board 1A according to the first embodiment of the invention, described above.

The electronic apparatus shown in FIGS. 8 to 13 implements a portable computer that transmits signals between a motherboard and hard disk drive (HDD) based on the Serial ATA-2 (SATA-2), using the flexible printed circuit board 1A, shown in FIGS. 1 to 7.

FIG. 8 shows the notebook-type portable computer 100. The portable computer 100 comprises a main body 102 and a display unit 103.

As shown in FIG. 8, the main body 102 comprises a first housing 110 that can be installed on a desk. The first housing 110 is shaped in form of a flat box and comprises a palm rest 111 and a keyboard mounting portion 112 on a top surface portion of the first housing 110. The palm rest 111 extends, in a front half of the first housing 110, along a width direction of the first housing 110. The keyboard mounting portion 112 is positioned behind the palm rest 111. A keyboard 113 is mounted in the keyboard mounting portion 112.

The first housing 110 comprises a pair of display support portions 114a and 114b located in the rear of the first housing 110 and separated from each other in the width direction.

The display unit 103 comprises a second housing 120 and for example, a liquid crystal display device 121 as a display device. The second housing 120 is formed in form of a flat box, and a display screen 121a of the liquid crystal display device 121 is exposed in a display opening 122.

The second housing 120 comprises a pair of leg portions 123a and 123b. The leg portions 123a and 123b are pivotally movably supported in the display support portions 114a and 114b of the first housing 110 via hinges (not shown). This pivotally moving mechanism allows the display unit 103 to move pivotally between a closed position where the display unit 103 covers the palm rest 111 and the keyboard 113 from above and an open position where the display unit 103 is raised upright to expose the palm rest 111 and keyboard 113.

As shown in FIGS. 9, 12, and 13, a space S is formed in the keyboard mounting portion 112 of the main body 102 below a mounting position of the keyboard 113 so that a hard disk drive 151 and a motherboard 170 are accommodated in the space S in juxtaposition.

The motherboard 170 and the hard disk drive 151 are mounted in the space S in the main body 102. The hard disk drive 151 and the motherboard 170 perform data read and write accesses via transmission lines for differential signals at a communication speed conforming to the Serial ATA-2.

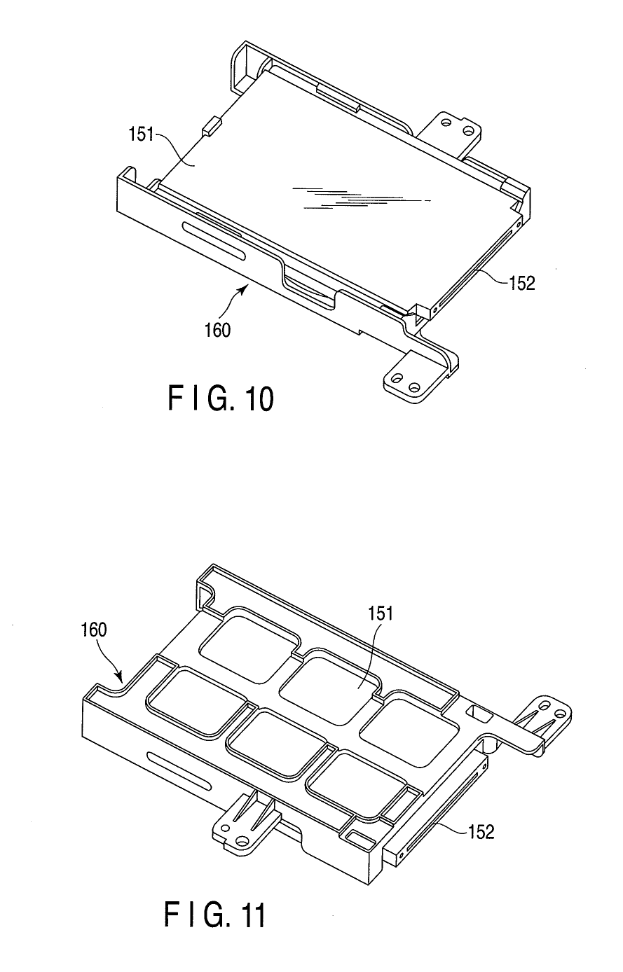

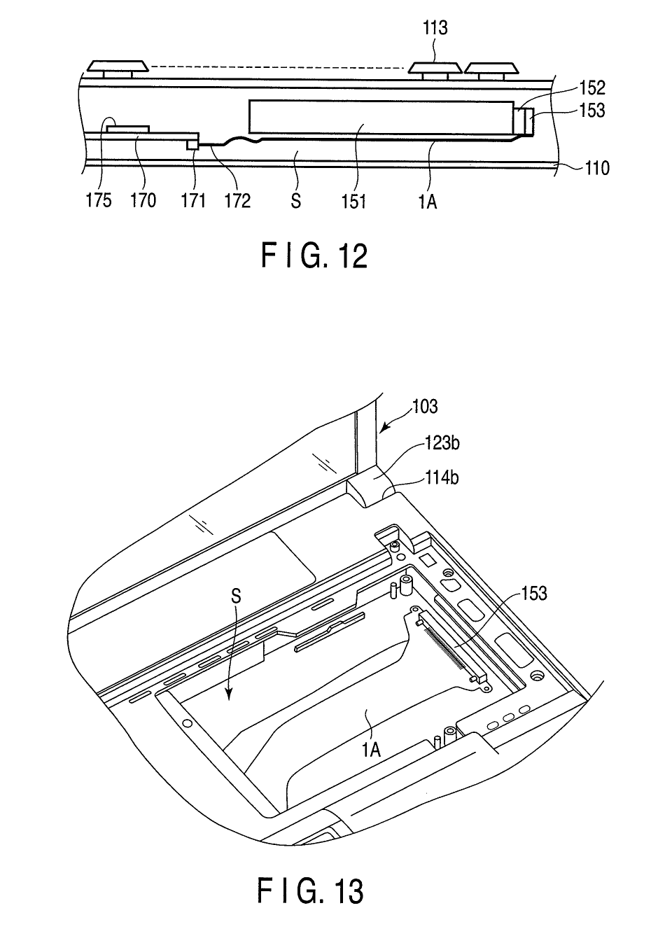

As shown in FIGS. 10 and 11, the hard disk drive 151 held in the case 160 is mounted in the space S in the main body 102 by a fastening mechanism (not shown). In FIG. 12, the case 160, which supports the hard disk drive 151, is omitted. The motherboard 170 is mounted in the space in the main body 102 in juxtaposition with the hard disk drive 151 by means of a fastening mechanism (not shown).

A CPU controlling the system and a peripheral circuit for the CPU are mounted on the motherboard 170. For example, a south bridge IC 175 mounted in the peripheral circuit for the CPU; the south bridge IC 175 makes up an I/O hub to which the hard disk drive 151 is connected so as to form a circuit. A connecter 170 (which comprises, for example, a crimping terminal of a lead insertion type) is mounted on the motherboard 170; the connecter 170 connects the hard disk drive 151 to the south bridge IC 175 so as to form a circuit.

The hard disk drive 151 comprises a connector (in this example, a connector receptacle) 152 making up an external connection interface mechanism.

The connector (connector receptacle) 152 of the hard disk drive 151 is connected to the connector (which comprises the crimping terminal of the lead insertion type) 171, mounted on the motherboard 170, via the flexible printed circuit board 1A shown in FIGS. 1 to 7 so as to form a circuit.

In the second embodiment, the flexible printed circuit board 1A connects an external connection interface of the hard disk drive 151 to an I/O connection interface of the motherboard 170 as transmission ends of information processing elements so as to form a circuit. The external connection interface of the hard disk drive 151 is the connector (connector receptacle) 152. The I/O connection interface of the motherboard 170 is the connector (which comprises the crimping terminal of the lead insertion type) 171, connected to the south bridge IC 175 so as to form a circuit.

The flexible printed circuit board 1A applied to the second embodiment offers a trace length from one side portion of the first housing 110 to a substantial center of the housing. The flexible printed circuit board 1A is located in the space S in the first housing 110 and between the hard disc 151 and the motherboard 170 so as to extend along a rear surface of the hard disk drive 151 and through a narrow space (a narrow gap corresponding to the entire space excluding component mounting areas) formed behind the hard disk drive 151 and serving as an installation path.

The flexible printed circuit board 1A comprises a connector (connector plug) 153 located at one end in a connection direction and coupled to a connector (connector receptacle) 152 of the hard disk drive 151. The flexible printed circuit board 1A also comprises a connecting lead terminal portion 172 located at one end in the connection direction and fittingly attached to the connector (which comprises the crimping terminal of the lead insertion type) 171, mounted on the motherboard 170.

The flexible printed circuit board 1A is installed in the installation path so that the connector (connector receptacle) 153, provided at one end of the flexible printed circuit board 1A in the connection direction, is coupled to the connector (connector receptacle) 152 of the hard disk drive 151 and so that the connecting lead terminal 172, provided at the other end of the flexible printed circuit board 1A in the connection direction, is fittingly attached (pressure bonded) to the connector (which comprises the crimping terminal of the lead insertion type) 171, mounted on the motherboard 170.

High-speed transmission of read and write data complying with the Serial ATA-2 specifications is performed between the hard disk drive 151 and the south bridge IC 175, mounted on the motherboard 170, via the flexible printed circuit board 1A.

This flexible printed circuit board 1A comprises the base layer 10, the signal layer 20 formed on the base layer 10, the cover layer 30 covering the signal layer 20, the metal layer 40 formed on the cover layer 30, the protective layer 50 formed on the metal layer 40, the conductive pattern portion 21 provided in the signal layer 20, the plurality of conductive-paste-filling openings CH each of which is shaped in form of a spot in the surface portion corresponding to the conductive pattern portion 21 in the cover layer 30 and which is made up of an opening, and the plurality of conductive portions 41 each comprising a conductive paste filled in the conductive-paste-filling opening CH to conductively join the metal layer 40 to the conductive pattern portion 21, as shown in FIG. 1. The conductive pattern portion 21 makes up the ground line forming a current path for a DC power supply. Signal transmission lines 22a and 22b that connect transmission ends of information processing elements together are formed in the signal layer 20 in a pattern layout in which the ground line 21 extends along the signal transmission lines 22a and 22b. The metal layer 40 forms the ground layer for the signal transmission lines 22a and 22b.

As described above, conductive paste is filled in the conductive-paste-filling opening CH formed in the cover layer 30 to form the conductive portion 41, which conductively joins the ground line 21 and the metal layer 40 together. Consequently, the metal film 42 of film thickness of at most 10 μm can be easily formed in the metal layer 40, and the metal film 42 is formed using the silver nanopaste with the low volume resistivity and inflicts a reduced transmission loss on the differential-signal transmission lines 22a and 22b. The metal film 42, formed using the silver nanopaste, makes up a ground pattern offering a low resistance for the differential-signal transmission lines 22a and 22b over the entire length of the transmission lines 22a and 22b to form a ground layer causing a reduced transmission loss. Thus, high-speed transmission of read and write data complying with the Serial ATA-2 specifications is performed between the hard disk drive 151 and the south bridge IC 175, mounted on the motherboard 170, via the flexible printed circuit board 1A. Furthermore, the flexible printed circuit board 1A of a single-sided shielding structure can be provided which is suitably applied to a narrow space (a narrow gap portion corresponding to the entire space excluding component mounting areas). This contributes to reducing the size and weight of the apparatus.

As has been described, the embodiments of the invention can avoid a possible transmission loss in the signal transmission line along which high-frequency-band signals are transmitted.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An apparatus, comprising:
a base layer;
a signal layer on the base layer, the signal layer comprising a conductive pattern;
a cover layer on the signal layer, the cover layer comprising a plurality of conductive-paste-filling openings aligned with the conductive pattern;
a metal layer on the cover layer;
a protective layer on the metal layer; and
a plurality of conductive portions between the conductive pattern and the metal layer, wherein the plurality of conductive portions are formed by filling conductive paste in the plurality of conductive-paste-filling openings,
wherein the metal layer comprises a metal film formed by a silver nanopaste with a thickness of at most 10 μm, and wherein the plurality of conductive portions are formed from a material other than the silver nanopaste.

2. The apparatus of claim 1, wherein the conductive pattern is configured to be a ground line of a direct current (DC) path, and the plurality of conductive portions conductively join the metal layer and the ground line.

3. The apparatus of claim 1, wherein:
the plurality of conductive portions form flat flanges on the cover layer, and
the metal layer covers both the cover layer and the conductive portions, including the flanges.

4. The apparatus of claim 1, wherein the metal film is configured to be a ground layer for a signal transmission line formed in the signal layer.

5. The apparatus of claim 4, wherein the signal transmission line is configured to transmit a high-frequency signal with a communication speed complying with a Serial ATA standard.

6. The apparatus of claim 5, wherein the signal transmission line for the high-frequency signal is formed in the signal layer as a pattern layout which comprises the ground line extending along the signal transmission line.

7. An electronic apparatus comprising:
a body;
a plurality of information processors comprising transmission ends for high-frequency signals; and
a circuit apparatus comprising a signal transmission line between the transmission ends of the information processors, the circuit apparatus comprising:
a base layer;
a signal layer on the base layer, the signal layer comprising a conductive pattern;
a cover layer on the signal layer, the cover layer comprising a plurality of conductive-paste-filling openings aligned with the conductive pattern;
a metal layer on the cover layer;
a protective layer on the metal layer; and
a plurality of conductive portions between the conductive pattern and the metal layer, wherein the plurality of conductive portions are formed by filling conductive paste in the plurality of conductive-paste-filling openings,
wherein the metal layer comprises a metal film formed by a silver nanopaste with a thickness of at most 10 μm, and wherein the plurality of conductive portions are formed from a material other than the silver nanopaste, and
wherein the conductive pattern portion is configured to be a ground line of a direct current (DC) path, a signal transmission line connecting transmission ends of information processors together being formed in the signal layer as a pattern layout which comprises the ground line extending along the signal transmission line, and the metal layer is configured to be a ground layer for the signal transmission line.

8. The electronic apparatus of claim 7, wherein the information processors are circuit components configured to transmit a high-frequency signal with a communication speed complying with a Serial ATA standard.
